(19) United States
(12) Patent Application Publication
(10) Pub. No.: US 2025/0157866 A1
(43) Pub. Date: May 15, 2025

(54) SILICON-ON-INSULATOR DEVICE INCLUDING CARRIER STRUCTURE

(71) Applicant: Micron Technology, Inc., Boise, ID (US)

(72) Inventors: Kamal M. KARDA, Boise, ID (US); Anthony J. KANAGO, Fremont, CA (US); Haitao LIU, Boise, ID (US); Si-Woo LEE, Saratoga, CA (US)

(21) Appl. No.: 18/949,509

(22) Filed: Nov. 15, 2024

Related U.S. Application Data
(60) Provisional application No. 63/599,425, filed on Nov. 15, 2023.

(51) Int. Cl. H01L 23/14; H10B 12/00; H10D 62/10; H10D 64/23

(52) U.S. Cl. CPC H01L 23/147; H10B 12/482; H10D 62/124; H10D 64/256

(57) ABSTRACT

Implementations described herein relate to various structures, integrated assemblies, and memory devices. In some implementations, a semiconductor device includes a carrier structure and a semiconductor structure. The semiconductor structure includes a silicon region having a first surface facing the carrier structure and a second, opposite surface facing away from the carrier structure. The semiconductor structure includes a gate structure on the first surface facing the carrier structure and an insulator region, where the insulator region is on the second, opposite surface facing away from the carrier structure.

### CROSS-REFERENCE TO RELATED APPLICATION

This Patent application claims priority to U.S. Provisional Patent Application No. 63/599,425, filed on Nov. 15, 2023, entitled “SILICON-ON-INSULATOR DEVICE INCLUDING CARRIER STRUCTURE,” and assigned to the assignee hereof. The disclosure of the prior Application is considered part of and is incorporated by reference into this Patent Application.

### TECHNICAL FIELD

The present disclosure generally relates to semiconductor devices and methods of forming semiconductor devices. For example, the present disclosure relates to a silicon-on-insulator device including a carrier structure.

### BACKGROUND

Memory devices are widely used to store information in various electronic devices. A memory device includes memory cells. A memory cell is an electronic circuit capable of being programmed to a data state of two or more data states. For example, a memory cell may be programmed to a data state that represents a single binary value, often denoted by a binary “1” or a binary “0.” As another example, a memory cell may be programmed to a data state that represents a fractional value (e.g., 0.5, 1.5, or the like). To store information, the electronic device may write, or program, a set of memory cells. To access the stored information, the electronic device may read, or sense, the stored state from the set of memory cells.

Various types of memory devices exist, including random access memory (RAM), read only memory (ROM), dynamic RAM (DRAM), static RAM (SRAM), synchronous dynamic RAM (SDRAM), ferroelectric RAM (FeRAM), magnetic RAM (MRAM), resistive RAM (RRAM), flash memory (e.g., NAND memory and NOR memory), and others. A memory device may be volatile or non-volatile. Non-volatile memory (e.g., flash memory) can store data for extended periods of time even in the absence of an external power source. Volatile memory (e.g., DRAM) may lose stored data over time unless the volatile memory is refreshed by a power source. A binary memory device may, for example, include a charged or discharged capacitor. A charged capacitor may, however, become discharged over time through leakage currents, resulting in the loss of the stored information. Some features of volatile memory may offer advantages, such as faster read or write speeds, while some features of non-volatile memory, such as the ability to store data without periodic refreshing, may be advantageous.

### BRIEF DESCRIPTION OF THE DRAWINGS

FIG. 1 is a circuit diagram of an example memory cell.

FIG. 2 is a diagrammatic side view of an example memory device described herein.

FIG. 3 is a flowchart of an example method of forming a memory device described herein.

FIGS. 4A-4J are diagrammatic side views showing an example process described here.

FIG. 5 is a diagrammatic view of an example memory device.

### DETAILED DESCRIPTION

A semiconductor device may include one or more device regions including a combination of dielectric layers and metallization layers that form integrated circuitry. For a dynamic random access memory (DRAM) type of semiconductor device, the device regions may include a memory device region and a transistor device region. The memory device region may include a memory array structure that includes an array of memory cells (e.g., capacitors for storing an electrical charge corresponding to values of “1” and “0”, respectively). The transistor device region may include transistor structures. Using a combination of digit lines structures (e.g., bit lines), access line structures, (e.g., word lines), and sensing structures (e.g., sense amps) that may be included within the semiconductor device, the transistor structures may control writing and/or reading values (e.g., electrical charges) to and/or from the array of memory cells.

In some cases, advances in manufacturing technology nodes (e.g., reductions in photolithography line widths governing feature sizes of the semiconductor device), in combination with architectures that reduce a size of the semiconductor device to gain manufacturing efficiencies, necessitate a use of a carrier structure to fabricate the semiconductor device. As an example, an architecture of the semiconductor device may include a memory cell that is patterned using an advanced photolithography line width, where the memory cell has a size that is approximately four times the area of a minimum, available feature size provided by the line width (e.g., a “4F2” memory cell). In such a case, the carrier structure (which may be permanent and included in a final product) may enable formation of a digit line that is “buried” in an isolation trench structure to be compatible with the 4F2 memory cell and reduce the size of the semiconductor device.

Some techniques to fabricate the semiconductor device including the permanent carrier structure may include forming recesses within the semiconductor device that create an offset (e.g., a “step height”) between integrated circuitry in transistor device region and integrated circuitry in the memory device region. The offset may add manufacturing steps to fabricate structures that are within and/or span regions of the transistor device region and/or the memory device region (e.g., the transistor structures, the memory array structure, the digit line structures, the access line structures, and/or the sensing structures). Other techniques to fabricate the semiconductor device including the carrier structure may require a thickness of a silicon region within the transistor device region (e.g., a silicon substrate for a transistor device within transistor device region) to be greater than approximately 400 nanometers. However, such a thickness may cause aspect ratios of the structures within and/or spanning regions of the semiconductor device (e.g., the Transistor device region, the memory device region, a peripheral region, and/or another region of the semiconductor device) to not satisfy thresholds that are compatible with patterning tools (e.g., photolithography tools) used to fabricate the semiconductor device. Not satisfying such thresholds may introduce a layout overhead (e.g., an increase in a design complexity) that introduces an area penalty (e.g., an increase in a size) to enable formation and/or routing of the structures.

Some implementations described herein include a semiconductor device and methods of formation. The semiconductor device includes a transistor device region and a memory device region on a carrier structure. The transistor device region, which conforms to a silicon-on-insulator architecture, includes a first silicon region having a first thickness, an insulator region on a first side of the silicon region, and a gate structure between the first silicon region and the carrier structure, where the gate structure is on a second, opposite side of the first silicon region. The memory device region includes a memory array structure and a second silicon region having a second thickness that is greater than the first thickness. Techniques to fabricate the semiconductor device may enable the first thickness to be less than approximately 250 nanometers (and also less than the second thickness). Additionally, or alternatively, the techniques described herein may eliminate an offset (e.g., the offset between the integrated circuitry within the transistor device region and the integrated circuitry within the memory device region) that may be included in other semiconductor devices formed using other techniques.

In this way, efforts to layout the semiconductor device (e.g., efforts by design engineers to design and arrange interrelated structures included in the semiconductor device) may be optimized and a size of the semiconductor device may be reduced. By optimizing the efforts to lay out the semiconductor device and reducing the size of the semiconductor device, an amount of resources needed to design and/or fabricate a volume of the semiconductor device (e.g., labor, computing resources, raw material, and/or semiconductor manufacturing tools) is reduced.

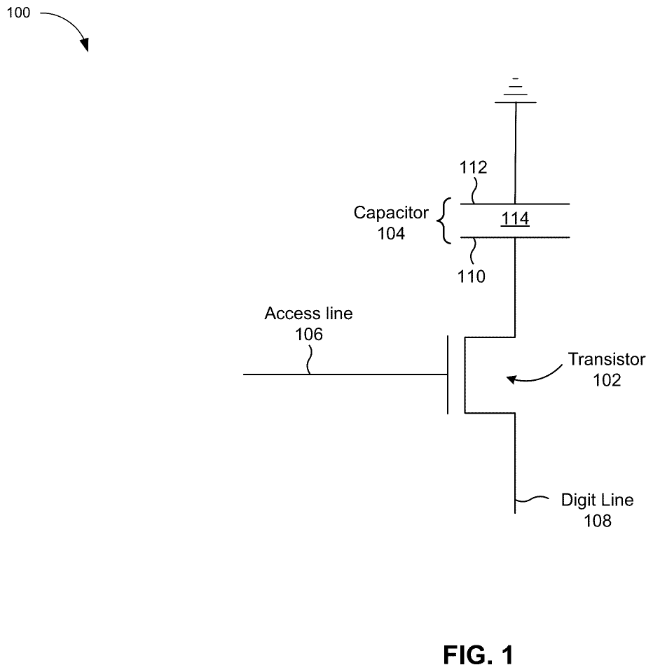

FIG. 1 is a circuit diagram of an example memory cell 100. In some implementations, the memory cell 100 is a dynamic random access memory cell. As illustrated in FIG. 1, the memory cell 100 may include a transistor 102 (or another type of selection circuit) and a capacitor 104. The memory cell 100 may be accessed (e.g., written to, read from, and/or erased) using signals on a combination of lines that are coupled to the memory cell 100, illustrated as an access line 106 (sometimes called a “word line”), and a digit line 108 (sometimes called a “bit line”).

The capacitor 104 includes a bottom electrode 110 and a top electrode 112 separated by an insulator 114. To write to (or program) the memory cell 100, the access line 106 may be activated, and a voltage may be applied across the capacitor 104 by controlling the voltage of the digit line 108. The applied voltage creates an electric field, and the atoms in the insulator 114 respond to the electric field to become arranged in a particular state (e.g., a particular orientation or polarization), which is representative of a data state (e.g., a logic “0” state or a logic “1” state). In some implementations, data may be stored using the capacitor 104 by controlling a voltage difference and/or a polarity difference of the capacitor 104 (e.g., of the insulator 114 between the bottom electrode 110 and the top electrode 112).

To read the memory cell 100 (e.g., a state stored by the capacitor 104), the access line 106 may be activated. The magnitude of the change in stored charge may depend on the stored state of capacitor 104 (e.g., whether the stored state is a logic “1” state or a logic “0” state). This may or may not induce a threshold change in the voltage of the digit line 108 based on the charge stored on the capacitor 104. The change in voltage or lack of change in voltage of the digit line 108 (or a magnitude of the change in voltage) may be used to determine the stored state of the capacitor 104. For example, if the change in voltage satisfies a threshold, then the read operation indicates that a first state was stored in the capacitor 104, whereas if the change in voltage does not satisfy the threshold, then the read operation determines that a second state was stored in the capacitor 104. In some cases, multiple threshold voltages may be used, such as when the capacitor is capable of storing more than two data states (e.g., for a multi-level cell, a triple-level cell, and so on).

As indicated above, FIG. 1 is provided as an example. Other examples may differ from what is described with respect to FIG. 1.

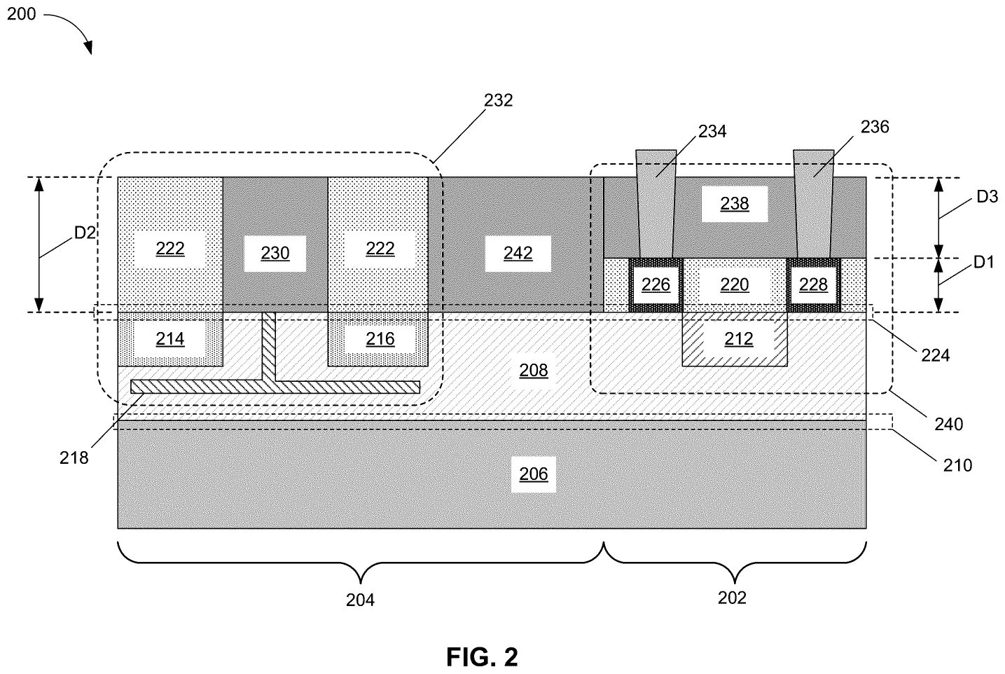

FIG. 2 is a diagrammatic side view of an example memory device 200 described herein. In some implementations, FIG. 2 includes example structural aspects of the memory cell 100 of FIG. 1. Furthermore, FIG. 2 may exclude portions of the memory cell 100 for clarity purposes. Furthermore, the memory device 200, or portions thereof, may be included in an integrated assembly configured to store data, such as a computing system, a memory card, an embedded multimedia card, a hard drive, and/or a solid-state drive (SSD), among other examples.

As illustrated in FIG. 2, the memory device 200 includes a transistor device region 202 and a memory device region 204 that are on a carrier structure 206. The carrier structure 206 may comprise, consist of, or consist essentially of silicon, borophosphosilicate glass, or ceramic, among other examples.

Regions and/or structures of the transistor device region 202 and the memory device region 204 may include combinations of one or more semiconductive materials, dielectric materials, and/or conductive materials. Semiconductive materials may comprise, consist of, or consist essentially of silicon (e.g., polycrystalline silicon), silicon germanium, gallium arsenide, indium phosphide, gallium nitride, silicon carbide, or a type III-V element, among other examples. Dielectric materials may comprise, consist of, or consist essentially of silicon dioxide, silicon nitride, and/or aluminum dioxide, among other examples. Conductive materials may comprise, consist of, or consist essentially of a metal (e.g., titanium, tungsten, cobalt, nickel, platinum, and/or ruthenium), a metal composition (e.g., a metal silicide, a metal carbide, and/or a metal nitride, such as titanium nitride or titanium silicon nitride), and/or a conductively-doped semiconductive material.

As illustrated in FIG. 2, dielectric region 208 is joined with the carrier structure 206. The dielectric region 208 may include one or more layers of dielectric materials. As illustrated in FIG. 2, the dielectric region 208 and the carrier structure 206 join along a same, approximately horizontal plane 210.

As further illustrated in FIG. 2, the transistor device region 202 and the memory device region 204 include structures in the dielectric region 208. For example, the transistor device region 202 includes a gate structure 212 in the dielectric region 208. The gate structure 212 (e.g., a gate structure of the transistor 102 of FIG. 2) may include a gate oxide substructure formed from a dielectric material and/or a gate contact substructure formed from a conductive material.

As another example, the memory device region 204 includes a digit line structure 214 and a digit line structure 216 in the dielectric region 208, where the digit line structures 214 and 216 are proximate to one another. The digit line structures 214 and 216 (e.g., digit line structures corresponding to the digit line 108 of FIG. 1) may include a conductive material.

In some implementations, and as illustrated in FIG. 2, the memory device region 204 includes a digit line shield structure 218 in the dielectric region 208, where the digit line shield structure 218 includes a portion between the digit line structures 214 and 216. The digit line shield structure 218 may include a dielectric material or a conductive material with electromagnetic wave shielding properties to prevent cross-talk between the digit line structures 214 and 216.

As further illustrated in FIG. 2, a semiconductor region 220 and a semiconductor region 222 are above the dielectric region 208. As illustrated in FIG. 2, the semiconductor region 220 and the semiconductor region 222 have surfaces that join with the dielectric region 208 along a same, approximately horizontal plane 224.

The semiconductor region 220 (e.g., an epitaxy region) may include silicon or another epitaxially grown semiconductive material, among other examples. The semiconductor region 222 (e.g., an epitaxy region) may include silicon or another epitaxially grown semiconductor material.

As further illustrated in FIG. 2, a thickness D1 of the semiconductor region 220 may be less than a thickness D2 of the semiconductor region 222. As an example, the thickness D1 may be approximately 150 microns, and the thickness D2 may be approximately 450 microns.

The semiconductor region 220 may include a source/drain region 226 and a source/drain region 228. The source/drain regions 226 and 228 (e.g., source/drain regions of the transistor 102 of FIG. 1) may each be a subregion of the semiconductor region 220 that is doped with a p-type impurity (e.g., boron) or an n-type impurity (e.g., arsenic).

The semiconductor region 222 may include memory cell structures that electrically connect with the digit line structure 214 and/or the digit line structure 216. Such memory cell structures may include storage structures (e.g., the capacitor 104 of FIG. 1) and access structures that connect the storage structures with the digit line structures 214 and 216.

As further illustrated in FIG. 2, an isolation region 230 may penetrate through the semiconductor region 222. The isolation region 230 (which may electrically isolate one or more structures included in the semiconductor region 222) may include a dielectric material. Furthermore, the isolation region 230 may have a same approximate thickness as the semiconductor region 222. In FIG. 2, the digit line structures 214 and 216, the digit line shield structures 218, the semiconductor region 222, and the isolation region 230 combine to form a memory array structure 232.

As further illustrated in FIG. 2, contact structures 234 and 236 penetrate through an insulator region 238 that is on and/or over the semiconductor region 220 to connect with the source/drain regions 226 and 228. The contact structures 234 and 236 may include a conductive material, and the insulator region 238 may include a dielectric material. The insulator region 238 may have a thickness D3 that is less than the thickness D2.

As further illustrated in FIG. 2, the semiconductor region 220 is joined with (e.g., “on”) the insulator region 238. A semiconductor structure 240 may include a portion of the dielectric region 208, the gate structure 212, the semiconductor region 220, the source/drain regions 226 and 228, the insulator region 238, and portions of the contact structures 234 and 236.

In an implementation in which the semiconductor region 220 includes a silicon material, the semiconductor structure 240 may be a “silicon-on-insulator” complementary metal oxide semiconductor (CMOS) structure. Such a structure may provide performance benefits for the memory device 200, including reduced parasitic capacitance, reduced leakage in a transistor structure that includes the gate structure 212, the semiconductor region 220, and the source/drain regions 226 and 228, and/or reduced power consumption relative to another memory device not including such a structure.

As further illustrated in FIG. 2, an isolation region 242 is between the semiconductor region 220 and the semiconductor region 222. The isolation region 242 may electrically isolate devices formed using the semiconductor regions 220 and 222. The isolation region 242 may include a dielectric material. Additionally, or alternatively, a thickness of the isolation region 242 may be a same approximate thickness as the thickness D2 of the semiconductor region 222. Additionally, or alternatively, the isolation region 242 may join with the insulator region 238. In some implementations, the insulator region 238 joins with the isolation region 242 above an edge of the semiconductor region 220 facing the isolation region 242.

As described in connection with FIG. 2, and elsewhere herein, surfaces of the semiconductor region 220 (e.g., the semiconductor region 220 of the transistor device region 202) and the semiconductor region 222 (e.g., the semiconductor region 222 of the memory device region 204) that face the dielectric region 208 share a same, approximately horizontal plane (e.g., the approximately horizontal plane 224). In other words, there is no vertical offset between the surfaces the transistor device region 202 and the memory device region 204 that cause significant topography differences between integrated circuitry (e.g., the source/drain regions 226 and 228, the gate structure 212, the digit line structures 214 and 216, the digit line shield structure 218, and or other memory cell structures that may be included in the semiconductor region 222).

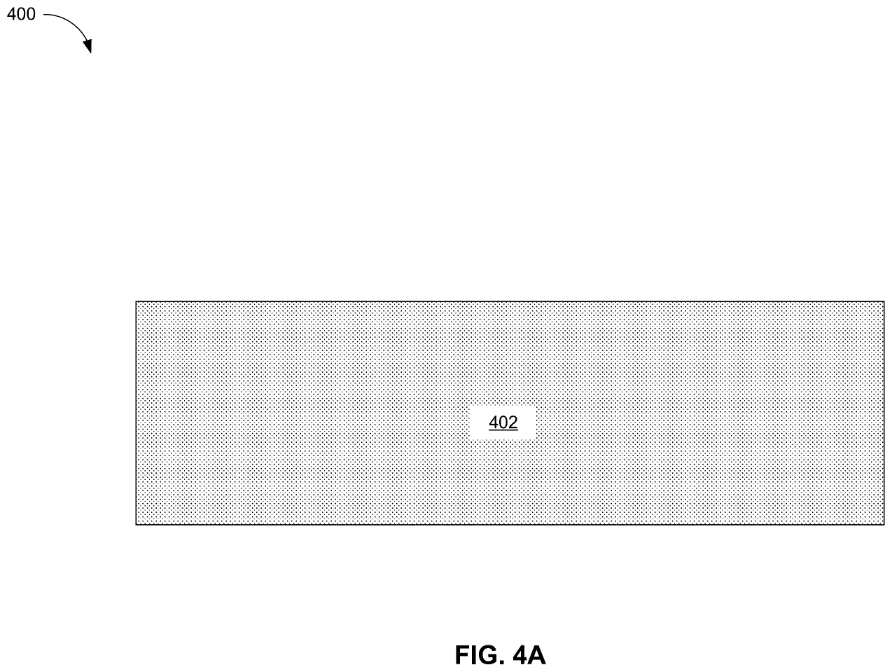

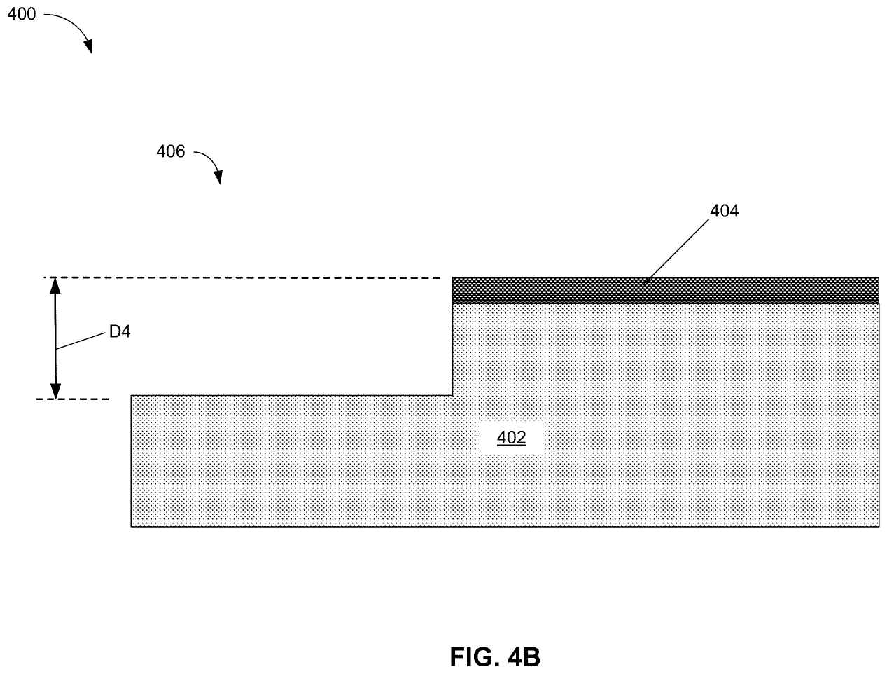

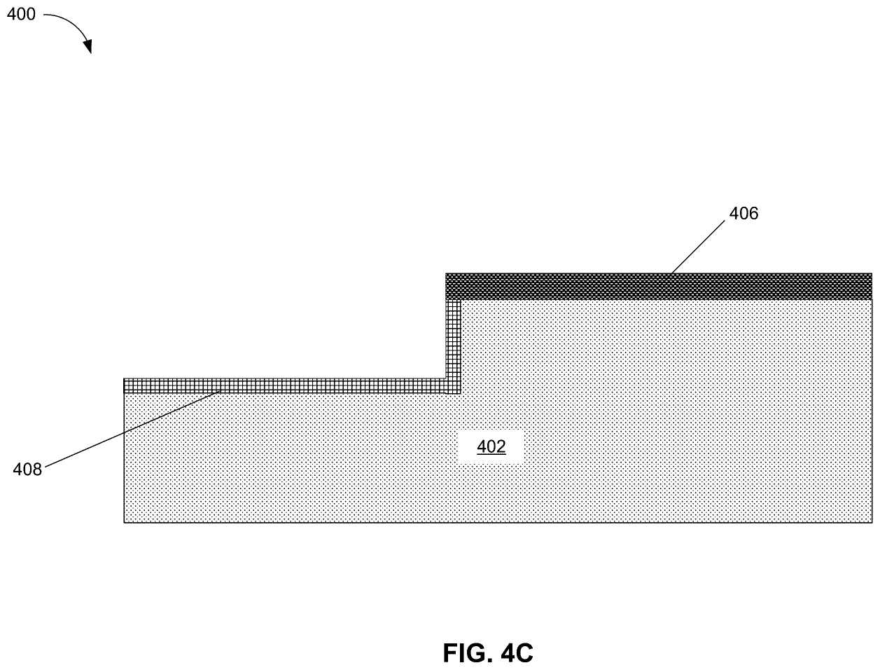

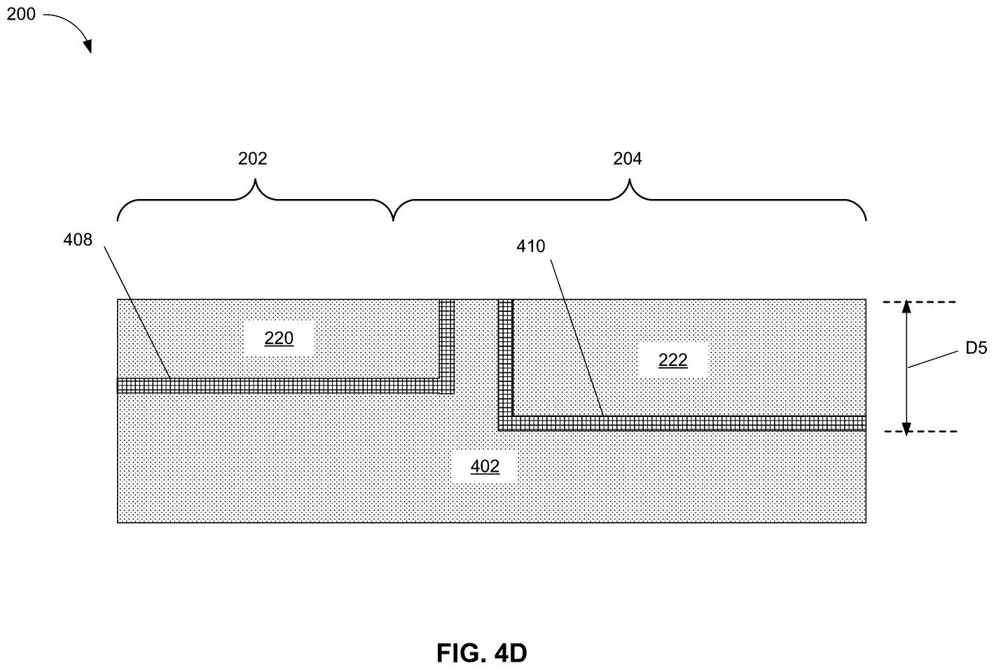

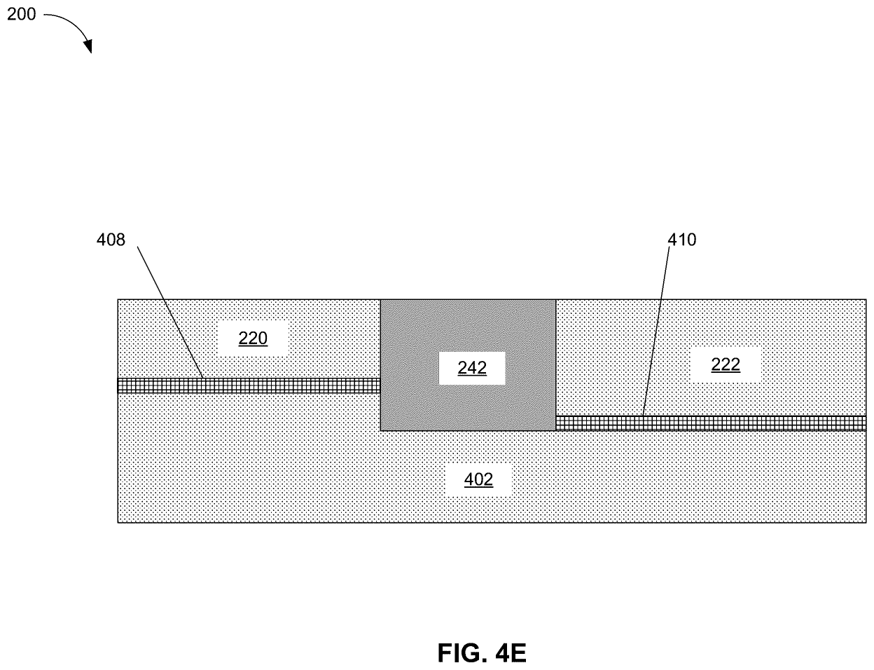

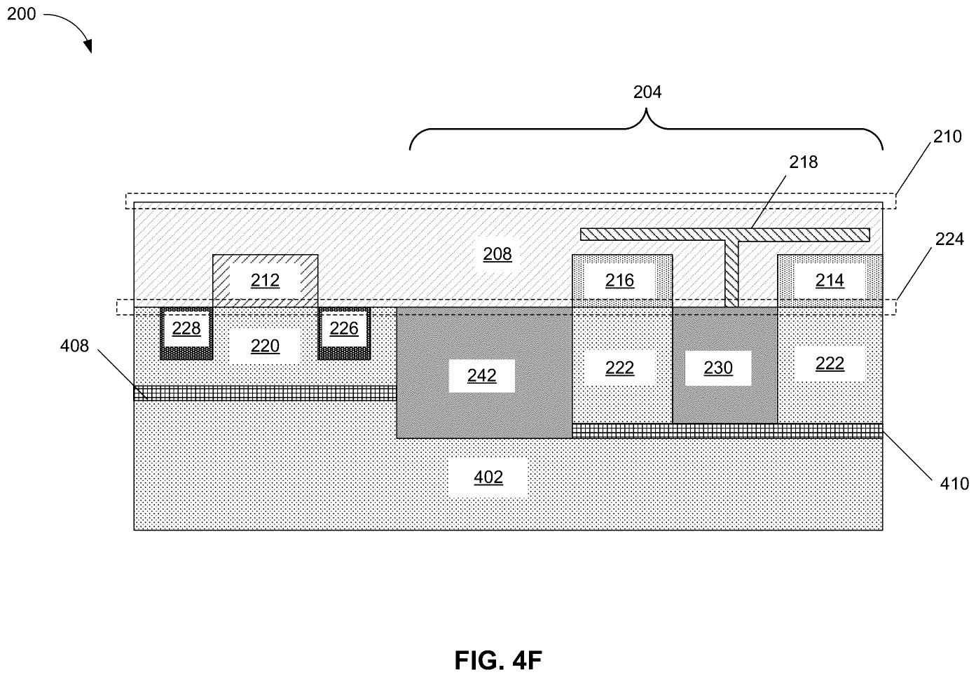

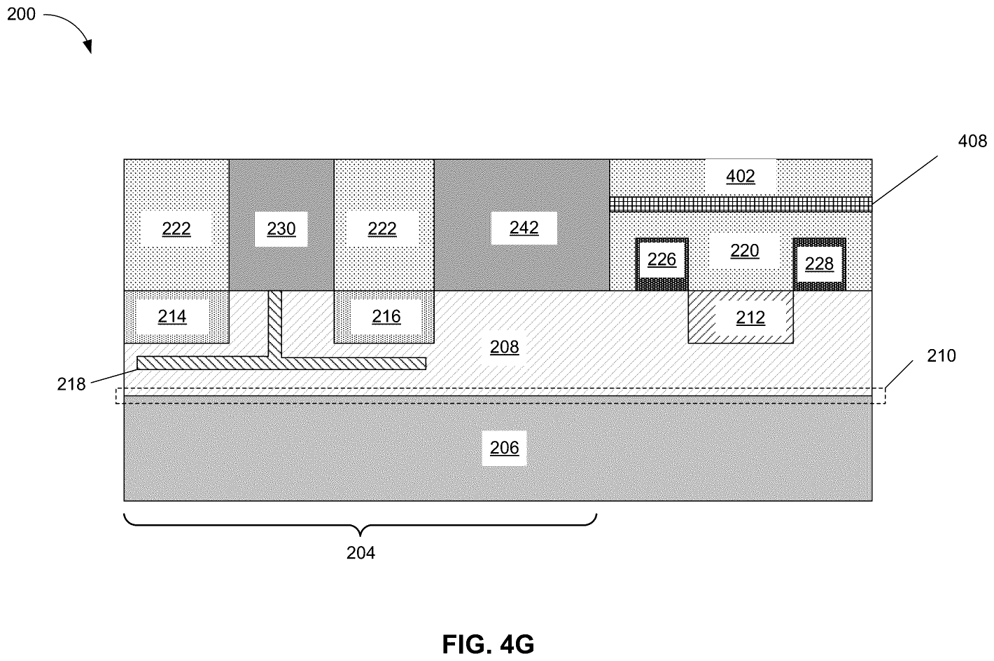

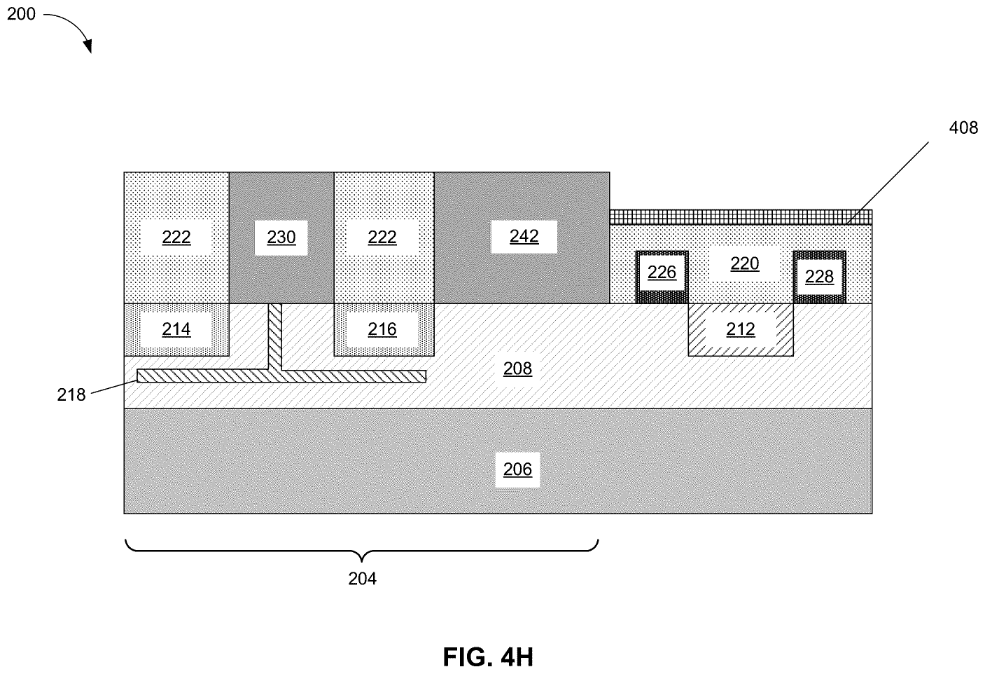

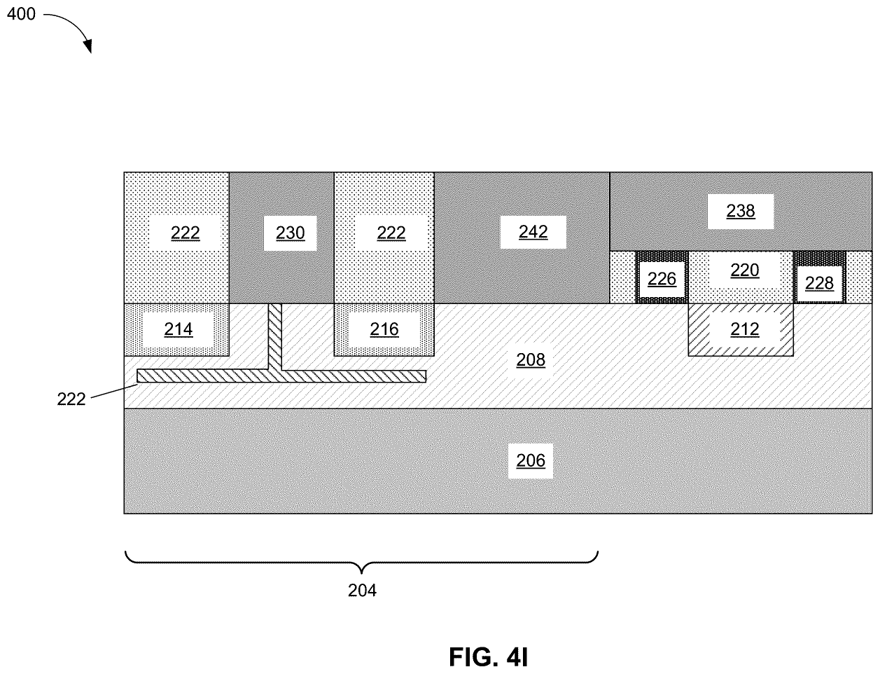

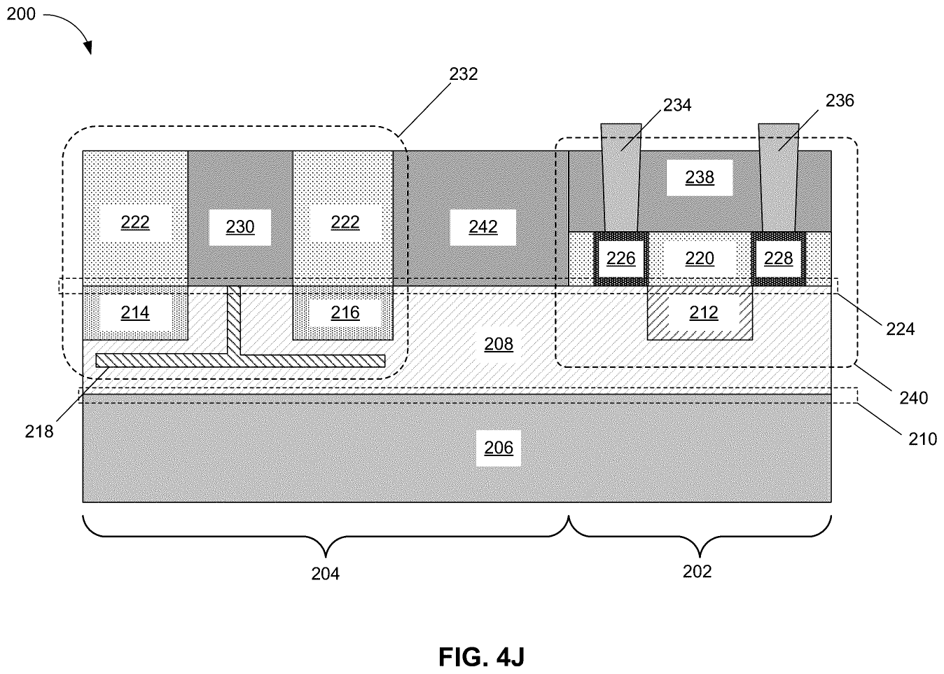

As further described in connection with FIG. 2, and elsewhere herein, an arrangement of the memory device 200 includes the gate structure 212 between the semiconductor region 220 and the carrier structure 206 (e.g., the gate structure 212 is on a surface of the semiconductor region 220 facing the carrier structure). As described in greater detail in connection with FIGS. 4A-4J, processes used to manufacture the memory device 200 (e.g., the memory device 200 including the gate structure 212 between the semiconductor region 220 and the carrier structure 206) enable the semiconductor region 220 to have a thickness that is reduced (e.g., D1 is less than approximately 150 microns) relative to another memory device that includes another gate structure on a surface of another silicon region that faces away from another carrier structure.

The elimination of the vertical offset, in combination with the thickness D1 of the semiconductor region 220, enables aspect ratios of the structures within the memory device 200 to satisfy thresholds (e.g., line width, depth of focus thresholds) that are compatible with patterning tools (e.g., photolithography tools) used to fabricate the memory device 200. Satisfying the thresholds may reduce layout overheads (e.g., increases in a design complexity due to layout and/or routing of structures across the memory device 200) and reduce a size of the memory device 200.

As indicated above, FIG. 2 is provided as an example. Other examples may differ from what is described with respect to FIG. 2.

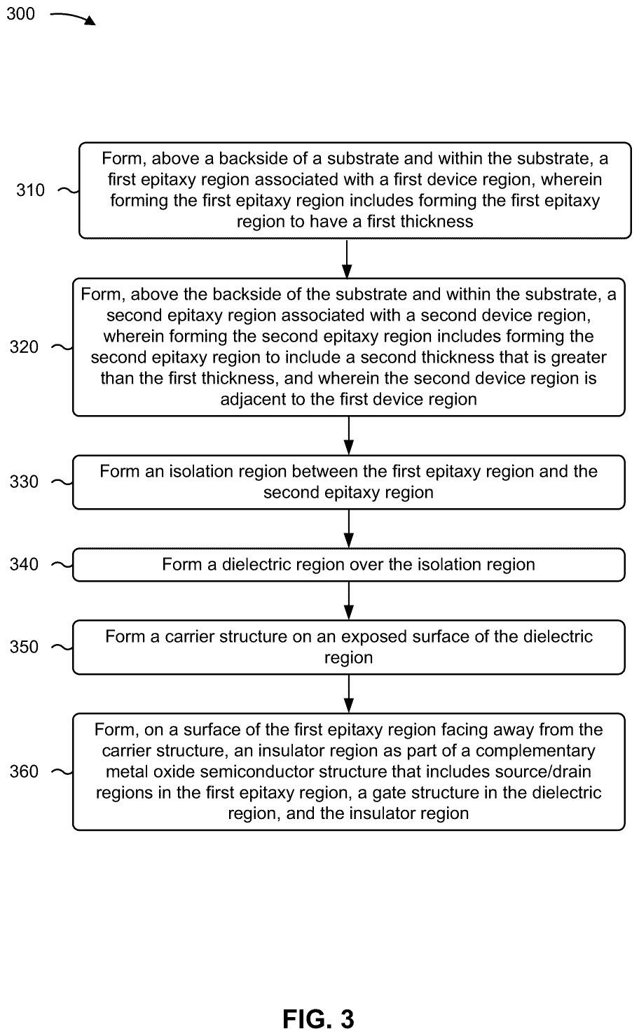

FIG. 3 is a flowchart of an example method 300 of forming a memory device described herein. In some implementations, one or more process blocks of FIG. 3 may be performed by various semiconductor manufacturing equipment. Furthermore, and in some implementations, the memory device is the memory device 200 described in connection with FIGS. 1 and 2.

As illustrated in FIG. 3, the method 300 may include forming, above a backside of a substrate and within the substrate, a first epitaxy region (e.g., the semiconductor region 220) associated with a first device region (e.g., the transistor device region 202), wherein forming the first epitaxy region includes forming the first epitaxy region to have a first thickness (e.g., the thickness D1) (block 310). As further shown in FIG. 3, the method 300 may include forming, above the backside of the substrate and within the substrate, a second epitaxy region (e.g., the semiconductor region 222) associated with a second device region (e.g., the memory device region 204), wherein forming the second epitaxy region includes forming the second epitaxy region to have a second thickness (e.g., the thickness D2) that is greater than the first thickness, and wherein the second device region is adjacent to the first device region (block 320). As further shown in FIG. 3, the method 300 may include forming an isolation region (e.g., the isolation region 242) between the first epitaxy region and the second epitaxy region (block 330). As further shown in FIG. 3, the method 300 may include forming a dielectric region (e.g., the dielectric region 208) over the isolation region (block 340). As further shown in FIG. 3, the method 300 may include forming a carrier structure (e.g., the carrier structure 206) on an exposed surface of the dielectric region (block 350). As further shown in FIG. 3, the method 300 may include forming, on a surface of the first epitaxy region facing away from the carrier structure, an insulator region (e.g., the insulator region 238) as part of a semiconductor structure (e.g., the semiconductor structure 240) that includes source/drain regions (e.g., the source/drain regions 226 and 228) in the first epitaxy region, a gate structure (e.g., the gate structure 212) in the dielectric region, and the insulator region (block 360).

The method 300 may include additional aspects, such as any single aspect or any combination of aspects described below and/or in connection with one or more other methods described elsewhere herein.

In a first aspect, forming the carrier structure on the exposed surface of the dielectric region includes bonding the carrier structure to the exposed surface of the dielectric region.

In a second aspect, alone or in combination with the first aspect, the method 300 includes forming a memory array structure (e.g., the memory array structure 232) using the second epitaxy region.

In a third aspect, alone or in combination with one or more of the first and second aspects, forming the first epitaxy region includes forming a first etch stop layer in a substrate at a first depth and epitaxially growing silicon on the first etch stop layer.

In a fourth aspect, alone or in combination with one or more of the first through third aspects, forming the second epitaxy region includes forming a second etch stop layer in the substrate at a second depth that is greater than the first depth and epitaxially growing silicon on the second etch stop layer.

Although FIG. 3 illustrates example blocks of the method 300, in some implementations, the method 300 may include additional blocks, fewer blocks, different blocks, or differently arranged blocks than those depicted in FIG. 3. In some implementations, the method 300 may include forming an integrated assembly that includes the memory device 200, any part described herein of the memory device 200, and/or any part described herein of an integrated assembly that includes the memory device 200. For example, the method 300 may include forming one or more of the semiconductor region 220, the semiconductor region 222, the gate structure 212, and/or the insulator region 238 in a type of semiconductor device or an integrated assembly that excludes a memory array structure (e.g., excludes the memory array structure 232).

FIGS. 4A through 4J are diagrammatic views showing formation of the memory device 200 at example process stages of an example process of forming the memory device 200. In some implementations, the example process described below in connection with FIGS. 4A through 4J may correspond to the method 300 and/or one or more blocks of the method 300. However, the process described below is an example, and other example processes may be used to form the memory device 200, an integrated assembly that includes the memory device 200, and/or one or more parts of the memory device 200 and/or the integrated assembly.

As illustrated in FIG. 4A, the process 400 may include use of a substrate 402. The substrate 402 may include a semiconductive material. The semiconductive material may comprise, consist of, or consist essentially of silicon (e.g., polycrystalline silicon), among other examples.

As illustrated in FIG. 4B, the process 400 may include forming (e.g., depositing, growing, and/or patterning) a mask structure 404 on the substrate 402. The mask structure 404 (e.g., a hard mask structure) may comprise, consist of, or consist essentially of silicon nitride, among other examples. As further shown in FIG. 4B, the process may include removing (e.g., etching) a portion of the substrate 402 not protected by the mask structure 404 to form a cavity 406 having a depth D4.

As illustrated in FIG. 4C, the process may include forming (e.g., depositing or epitaxially growing) a material 408 on surfaces of the cavity 406. The material 408 may comprise, consist of, or consist essentially of silicon germanium, among other examples.

As shown in FIG. 4D, the process 400 may include forming the semiconductor region 220 on and/or over the material 408. Forming the semiconductor region 220 may include forming (e.g., depositing, epitaxially growing) a semiconductive material that may comprise, consist of, or consist essentially of silicon (e.g., polycrystalline silicon), among other examples. In some implementations, forming the semiconductor region 220 includes planarizing the semiconductive material using a chemical-mechanical polishing (CMP) technique or another suitable planarization technique.

As further shown in FIG. 4D and using techniques similar to those described in connection with FIGS. 4B and 4C, the process 400 may include forming a layer of material 410 on surfaces of a cavity having a depth D5 in the substrate 402, where the depth D5 is greater than the depth D4 of FIG. 4C. The material 410 may comprise, consist of, or consist essentially of silicon germanium, among other examples. The process 400 may include forming the semiconductor region 222 on the layer of material 410. Forming semiconductor region 222 may include forming (e.g., depositing, growing) a semiconductive material that may comprise, consist of, or consist essentially of silicon (e.g., polycrystalline silicon), among other examples. In some implementations, forming the semiconductor region 222 includes planarizing the semiconductive material using a CMP technique or another suitable planarization technique.

As illustrated in FIG. 4E, the process 400 may include forming the isolation region 242 between the semiconductor region 220 and the semiconductor region 222. Forming the isolation region 242 may include removing (e.g., etching) portions of the semiconductor region 220, the semiconductor region 222, the material 408, the material 410, and/or the substrate 402 to form a cavity between the semiconductor region 220 and the semiconductor region 222. Forming the isolation region 242 may include forming (e.g., depositing) a dielectric material in the cavity. The dielectric material may comprise, consist of, or consist essentially of silicon dioxide, silicon nitride, and/or aluminum dioxide, among other examples. In some implementations, forming the isolation region 242 includes planarizing the isolation region 242 using a CMP technique or another suitable planarization techniques.

As illustrated in FIG. 4F, the process 400 may include forming the isolation region 230 that penetrates through the semiconductor region 222. Forming the isolation region 230 may include removing (e.g., etching) portions of the semiconductor region 222 to form a cavity in the semiconductor region 222. Forming the isolation region 230 may include forming (e.g., depositing) a dielectric material in the cavity. The dielectric material may comprise, consist of, or consist essentially of silicon dioxide, silicon nitride, and/or aluminum dioxide, among other examples. In some implementations, forming the isolation region 230 includes planarizing the isolation region 230 using a CMP technique or another suitable planarization technique.

As further shown in FIG. 4F, the process 400 may include forming the source/drain region 226 and the source/drain region 228 in the semiconductor region 220. Forming the source/drain region 226 and the source/drain region 228 may include doping portions of the semiconductor region 220 using ion implantation.

As further shown in FIG. 4F, the process 400 may include forming the gate structure 212. Forming the gate structure 212 may include forming a gate oxide substructure and a gate contact substructure on and/or over the semiconductor region 220. The gate oxide substructure may comprise, consist of, or consist essentially of a dielectric material such as silicon dioxide, among other examples. The gate contact substructure may comprise, consist of, or consist essentially of a conductive material such as a metal (e.g., titanium, tungsten, cobalt, nickel, platinum, and/or ruthenium), a metal composition (e.g., a metal silicide, a metal carbide, and/or a metal nitride, such as titanium nitride or titanium silicon nitride), and/or a conductively-doped semiconductor material (e.g., conductively-doped polysilicon, conductively-doped germanium, and/or conductively-doped gallium arsenide), among other examples. In some implementations, one or more masks may be used to form the gate structure 212. For example, one or more masks may be deposited and/or patterned on the dielectric material and/or the conductive material prior to removing portions of the dielectric material and/or the conductive material to form the gate structure 212.

As further shown in FIG. 4F, the process 400 may include forming the digit line structure 214 and the digit line structure 216. Forming the digit line structure 214 and the digit line structure 216 may include forming (e.g., depositing) a conductive material on and/or over the semiconductor region 222. The conductive material may comprise, consist of, or consist essentially of a metal (e.g., titanium, tungsten, cobalt, nickel, platinum, and/or ruthenium), a metal composition (e.g., a metal silicide, a metal carbide, and/or a metal nitride, such as titanium nitride or titanium silicon nitride), and/or a conductively-doped semiconductor material (e.g., conductively-doped polysilicon, conductively-doped germanium, and/or conductively-doped gallium arsenide), among other examples. In some implementations, one or more masks may be used to form the digit line structure 214 and the digit line structure 216. For example, one or more masks may be deposited and/or patterned on the conductive material prior to removing a portion of the conductive material to form the digit line structure 214 and/or the digit line structure 216.

As further shown in FIG. 4F, the process 400 may include forming the digit line shield structure 218 on and/or over the semiconductor region 222. Forming the digit line shield structure 218 include forming (e.g., depositing) layers of a conductive material over the isolation region 230 and/or the semiconductor region 222. The conductive material may comprise, consist of, or consist essentially of a metal (e.g., titanium, tungsten, cobalt, nickel, platinum, and/or ruthenium), a metal composition (e.g., a metal silicide, a metal carbide, and/or a metal nitride, such as titanium nitride or titanium silicon nitride), and/or a conductively-doped semiconductor material (e.g., conductively-doped polysilicon, conductively-doped germanium, and/or conductively-doped gallium arsenide), among other examples. In some implementations, one or more masks may be deposited and/or patterned on the layers of the conductive material prior to removing portions of the layers of the conductive material to form the digit line shield structure.

As further shown in FIG. 4F, the process 400 may include forming the dielectric region 208 over and/or on the semiconductor regions 220 and 222. Forming the dielectric region 208 may include interspersing one or more layers of dielectric materials on, over, and/or amongst the materials (e.g., layers of the materials) used to form the gate structure 212, the digit line structures 214 and 216, and/or the digit line shield structure 218. The one or more layers of dielectric materials may comprise, consist of, or consist essentially of silicon dioxide, silicon nitride, and/or aluminum dioxide, among other examples. In some implementations, a surface of the dielectric region 208 is planarized using a CMP technique or another suitable planarization technique.

As illustrated in FIG. 4G, the process 400 may include joining an exposed, top surface of the dielectric region 208 and the carrier structure 206 along the approximately horizontal plane 210 (e.g., a bond interface region). In some implementations, joining the dielectric region 208 and the carrier structure 206 includes subjecting the dielectric region 208 and the carrier structure 206 to pressure and/or heat to form a bond along the approximately horizontal plane 210.

As shown in FIG. 4H, the process 400 may include removing (e.g., etching) a remaining portion of the substrate 402. The removing may remove the remaining portion of the substrate 402 to the material 408 (e.g., the material 408 may perform as an etch stop layer).

As shown in FIG. 4I, the process 400 may include forming the insulator region 238 on and/or over the semiconductor region 220, the gate structure 212, the source/drain region 226, and/or the source/drain region 228. Forming the insulator region 238 may include removing (e.g., etching) the material 408 and a portion of the semiconductor region 220 to the gate structure 212, the source/drain region 226, and/or the source/drain region 228 to form a cavity. Forming the insulator region 238 may further include forming, in the cavity, a dielectric material over and/or on the semiconductor region 220, the gate structure 212, the source/drain region 226, and/or the source/drain region 228. The dielectric material may comprise, consist of, or consist essentially of silicon dioxide, silicon nitride, and/or aluminum dioxide, among other examples. In some implementations, a surface of the insulator region 238 is planarized using a CMP technique or another suitable planarization technique.

As illustrated in FIG. 4J, the process 400 includes forming the contact structure 234 through the insulator region 238 to the source/drain region 226 and forming the contact structure 236 through the insulator region 238 to the source/drain region 228. Forming the contact structures 234 and 236 may include removing (e.g., etching) portions of the insulator region 238 to form cavities through the insulator region 238 to the source/drain regions 226 and 228. Forming the contact structures 234 and 236 may further include depositing, in the cavities, a conductive material on the source/drain regions 226 and 228. The conductive material may comprise, consist of, or consist essentially of a metal (e.g., titanium, tungsten, cobalt, nickel, platinum, and/or ruthenium), a metal composition (e.g., a metal silicide, a metal carbide, and/or a metal nitride, such as titanium nitride or titanium silicon nitride), and/or a conductively-doped semiconductor material (e.g., conductively-doped polysilicon, conductively-doped germanium, and/or conductively-doped gallium arsenide), among other examples. As further shown in FIG. 4J, the transistor device region 202 includes the semiconductor structure 240.

As indicated above, the process steps described in connection with FIGS. 4A through 4J are provided as examples. Other examples may differ from what is described with respect to FIGS. 4A through 4J. The structure shown in FIG. 4J may be equivalent to the memory device 200 described elsewhere herein. In process steps above that describe forming material, such material may be formed, for example, using chemical vapor deposition, atomic layer deposition, physical vapor deposition, or another deposition technique. In process steps above that describe removing material, such material may be removed, for example, using a wet etching technique (e.g., wet chemical etching), a dry etching technique (e.g., plasma etching), an ion etching technique (e.g., sputtering or reactive ion etching), atomic layer etching, or another etching technique.

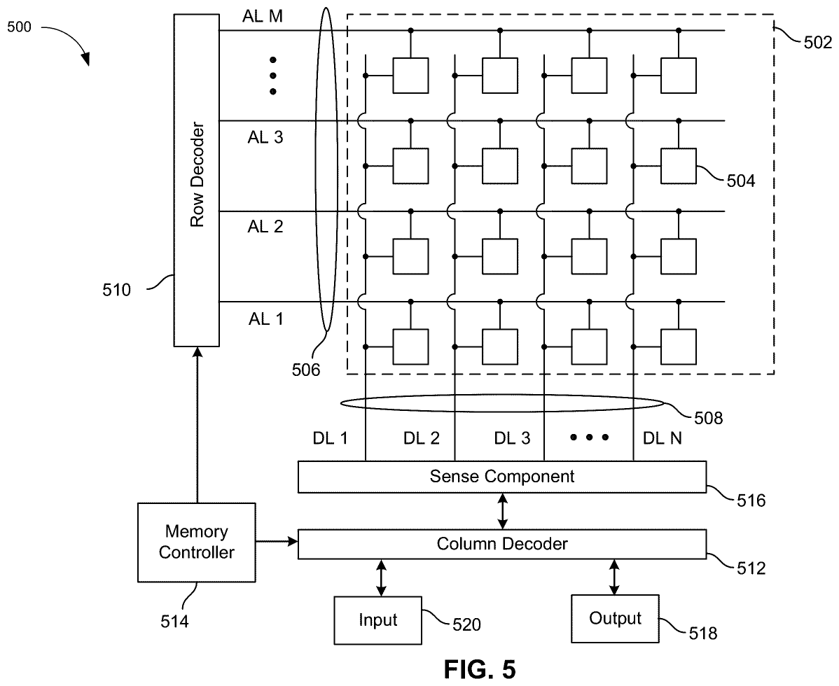

FIG. 5 is a diagrammatic view of an example memory device 500. The memory device 500 (e.g., the memory device 200 of FIG. 2) may include a memory array 502 that includes multiple memory cells 504 (e.g., multiples of the memory cell 100 of FIG. 1). A memory cell 504 is programmable or configurable into a data state of multiple data states (e.g., two or more data states). For example, a memory cell 504 may be set to a particular data state at a particular time, and the memory cell 504 may be set to another data state at another time. A data state may correspond to a value stored by the memory cell 504. The value may be a binary value, such as a binary 0 or a binary 1, or may be a fractional value, such as 0.5, 1.5, or the like. A memory cell 504 may include a capacitor to store a charge representative of the data state. For example, a charged and an uncharged capacitor may represent a first data state and a second data state, respectively. As another example, a first level of charge (e.g., fully charged) may represent a first data state, a second level of charge (e.g., fully discharged) may represent a second data state, a third level of charge (e.g., partially charged) may represent a third data state, and so on.

Operations such as reading and writing (i.e., cycling) may be performed on memory cells 504 by activating or selecting the appropriate access line 506 (e.g., the access line 106 of FIG. 1, shown as access lines AL 1 through AL M) and digit line 508 (e.g., the digit line 108 of FIG. 1, shown as digit lines DL 1 through DL N). An access line 506 may also be referred to as a “row line” or a “word line,” and a digit line 508 may also be referred to a “column line” or a “bit line.” Activating or selecting an access line 506 or a digit line 508 may include applying a voltage to the respective line. An access line 506 and/or a digit line 508 may comprise, consist of, or consist essentially of a conductive material, such as a metal (e.g., copper, aluminum, gold, titanium, or tungsten) and/or a metal alloy, among other examples. In FIG. 5, each row of memory cells 504 is connected to a single access line 506, and each column of memory cells 504 is connected to a single digit line 508. By activating one access line 506 and one digit line 508 (e.g., applying a voltage to the access line 506 and digit line 508), a single memory cell 504 may be accessed at (e.g., is accessible via) the intersection of the access line 506 and the digit line 508. The intersection of the access line 506 and the digit line 508 may be called an “address” of a memory cell 504.

In some implementations, the logic storing device of a memory cell 504, such as a capacitor, may be electrically isolated from a corresponding digit line 508 by a selection component, such as a transistor. The access line 506 may be connected to and may control the selection component. For example, the selection component may be a transistor, and the access line 506 may be connected to the gate of the transistor. Activating the access line 506 results in an electrical connection or closed circuit between the capacitor of a memory cell 504 and a corresponding digit line 508. The digit line 508 may then be accessed (e.g., is accessible) to either read from or write to the memory cell 504.

A row decoder 510 and a column decoder 512 may control access to memory cells 504. For example, the row decoder 510 may receive a row address from a memory controller 514 and may activate the appropriate access line 506 based on the received row address. Similarly, the column decoder 512 may receive a column address from the memory controller 514 and may activate the appropriate digit line 508 based on the column address.

Upon accessing a memory cell 504, the memory cell 504 may be read (e.g., sensed) by a sense component 516 to determine the stored data state of the memory cell 504. For example, after accessing the memory cell 504, the capacitor of the memory cell 504 may discharge onto its corresponding digit line 508. Discharging the capacitor may be based on biasing, or applying a voltage, to the capacitor. The discharging may induce a change in the voltage of the digit line 508, which the sense component 516 may compare to a reference voltage (not shown) to determine the stored data state of the memory cell 504. For example, if the digit line 508 has a higher voltage than the reference voltage, then the sense component 516 may determine that the stored data state of the memory cell 504 corresponds to a first value, such as a binary 1. Conversely, if the digit line 508 has a lower voltage than the reference voltage, then the sense component 516 may determine that the stored data state of the memory cell 504 corresponds to a second value, such as a binary 0. The detected data state of the memory cell 504 may then be output (e.g., via the column decoder 512) to an output component 518 (e.g., a data buffer). A memory cell 504 may be written (e.g., set) by activating the appropriate access line 506 and digit line 508. The column decoder 512 may receive data, such as input from input component 520, to be written to one or more memory cells 504. A memory cell 504 may be written by applying a voltage across the capacitor of the memory cell 504.

The memory controller 514 may control the operation (e.g., read, write, re-write, refresh, and/or recovery) of the memory cells 504 via the row decoder 510, the column decoder 512, and/or the sense component 516. The memory controller 514 may generate row address signals and column address signals to activate the desired access line 506 and digit line 508. The memory controller 514 may also generate and control various voltages used during the operation of the memory array 502.

As indicated above, FIG. 5 is provided as an example. Other examples may differ from what is described with respect to FIG. 5.

In some implementations, an integrated assembly includes a carrier structure (e.g., the carrier structure 206); a semiconductor structure (e.g., the semiconductor structure 240), comprising: an epitaxy region (e.g., the semiconductor region 220), comprising: a first surface facing the carrier structure; and a second, opposite surface facing away from the carrier structure; and a gate structure (e.g., the gate structure 212), wherein the gate structure is on the first surface facing the carrier structure; an insulator region (e.g., the insulator region 238), wherein the insulator region is on the second, opposite surface facing away from the carrier structure; and first and second source/drain regions (e.g., the source/drain regions 226 and 228), wherein the first and second source/drain regions are in the epitaxy region.

In some implementations, an apparatus (e.g., the memory device 200) includes a carrier structure (e.g., the carrier structure 206); a dielectric region (e.g., the dielectric region 208; on the carrier structure; a gate structure (e.g., the gate structure 212) in the dielectric region; a digit line shield structure (e.g., the digit line shield structure 218) proximate to the gate structure in the dielectric region; a first silicon region (e.g., the semiconductor region 220) on the dielectric region, above the gate structure, and having a first thickness (e.g., the thickness D1); source/drain regions (e.g., the source/drain regions 226 and 228) in the first silicon region; a second silicon region (e.g., the semiconductor region 222) on the dielectric region, proximate to the first silicon region, and having a second thickness (e.g., the thickness D2) that is greater than the first thickness; and an isolation region (e.g., the isolation region 242) between the first silicon region and the second silicon region and having a same approximate thickness as the second thickness.

In some implementations, an apparatus (e.g., the memory device 200) includes a carrier structure (e.g., the carrier structure 206); a first device region (e.g., the transistor device region 202), comprising: a silicon-on-insulator semiconductor structure (e.g., a silicon-on-insulator implementation of the semiconductor structure 240), comprising: a first silicon region (e.g., the semiconductor region 220) over a dielectric region (e.g., the dielectric region 208); an insulator region (e.g., the insulator region 238) on the first silicon region; and a gate structure (e.g., the gate structure 212), wherein the gate structure is between the insulator region and the carrier structure; and a second device region (e.g., the memory device region 204), comprising: a memory array structure (e.g., the memory array structure 232), comprising: a second silicon region (e.g., the semiconductor region 222) over the dielectric region, wherein the second silicon region is proximate to the first silicon region, and wherein surfaces of the first silicon region and the second silicon region that face the carrier structure share a same, approximately horizontal plane (e.g., the approximately horizontal plane 224) with a surface of the dielectric region that faces away from the carrier structure.

In some implementations, a method (e.g., the method 300) includes forming, above a backside of a substrate (e.g., the substrate 402) and within the substrate, a first epitaxy region (e.g. the semiconductor region 220) associated with a first device region (e.g., the transistor device region 202), wherein forming the first epitaxy region includes forming the first epitaxy region to have a first thickness (e.g., the thickness D1); forming, above the backside of the substrate and within the substrate, a second epitaxy region (e.g., the semiconductor region 222) associated with a second device region (e.g., the memory device region 204), wherein forming the second epitaxy region includes forming the second epitaxy region to have a second thickness (e.g., the thickness D2) that is greater than the first thickness, and wherein the second device region is adjacent to the first device region; forming an isolation region (e.g., the isolation region 242) between the first epitaxy region and the second epitaxy region; forming a dielectric region (e.g., the dielectric region 208) over the isolation region; forming a carrier structure (e.g., the carrier structure 206) on an exposed surface of the dielectric region; and forming, on a surface of the first epitaxy region facing away from the carrier structure, an insulator region (e.g., the insulator region 238) as part of a semiconductor structure (e.g., the semiconductor structure 240) that includes source/drain regions (e.g., the source/drain regions 226 and 228) in the first epitaxy region, a gate structure (e.g., the gate structure 212) in the dielectric region, and the insulator region.

The foregoing disclosure provides illustration and description but is not intended to be exhaustive or to limit the implementations to the precise forms disclosed. Modifications and variations may be made in light of the above disclosure or may be acquired from practice of the implementations described herein.

The orientations of the various elements in the figures are shown as examples, and the illustrated examples may be rotated relative to the depicted orientations. The descriptions provided herein, and the claims that follow, pertain to any structures that have the described relationships between various features, regardless of whether the structures are in the particular orientation of the drawings, or are rotated relative to such orientation. Similarly, spatially relative terms, such as “below,” “beneath,” “lower,” “above,” “upper,” “middle,” “left,” and “right,” are used herein for ease of description to describe one element's relationship to one or more other elements as illustrated in the figures. The spatially relative terms are intended to encompass different orientations of the element, structure, and/or assembly in use or operation in addition to the orientations depicted in the figures. A structure and/or assembly may be otherwise oriented (rotated 50 degrees or at other orientations), and the spatially relative descriptors used herein may be interpreted accordingly. Furthermore, the cross-sectional views in the figures only show features within the planes of the cross-sections, and do not show materials behind the planes of the cross-sections, unless indicated otherwise, in order to simplify the drawings.

As used herein, the terms “substantially” and “approximately” mean “within reasonable tolerances of manufacturing and measurement.” As used herein, “satisfying a threshold” may, depending on the context, refer to a value being greater than the threshold, greater than or equal to the threshold, less than the threshold, less than or equal to the threshold, equal to the threshold, not equal to the threshold, or the like. All ranges described herein are inclusive of numbers at the ends of those ranges, unless specifically indicated otherwise.

Even though particular combinations of features are recited in the claims and/or disclosed in the specification, these combinations are not intended to limit the disclosure of implementations described herein. Many of these features may be combined in ways not specifically recited in the claims and/or disclosed in the specification. For example, the disclosure includes each dependent claim in a claim set in combination with every other individual claim in that claim set and every combination of multiple claims in that claim set. As used herein, a phrase referring to “at least one of” a list of items refers to any combination of those items, including single members. As an example, “at least one of: a, b, or c” is intended to cover a, b, c, a+b, a+c, b+c, and a+b+c, as well as any combination with multiples of the same element (e.g., a+a, a+a+a, a+a+b, a+a+c, a+b+b, a+c+c, b+b, b+b+b, b+b+c, c+c, and c+c+c, or any other ordering of a, b, and c).

No element, act, or instruction used herein should be construed as critical or essential unless explicitly described as such. Also, as used herein, the articles “a” and “an” are intended to include one or more items and may be used interchangeably with “one or more.” Further, as used herein, the article “the” is intended to include one or more items referenced in connection with the article “the” and may be used interchangeably with “the one or more.” Where only one item is intended, the phrase “only one,” “single,” or similar language is used. Also, as used herein, the terms “has,” “have,” “having,” or the like are intended to be open-ended terms that do not limit an element that they modify (e.g., an element “having” A may also have B). Further, the phrase “based on” is intended to mean “based, at least in part, on” unless explicitly stated otherwise. As used herein, the term “multiple” can be replaced with “a plurality of” and vice versa. Also, as used herein, the term “or” is intended to be inclusive when used in a series and may be used interchangeably with “and/or,” unless explicitly stated otherwise (e.g., if used in combination with “either” or “only one of”).

What is claimed is:

1. An integrated assembly, comprising:
a carrier structure;
a semiconductor structure, comprising:
an epitaxy region, comprising:
a first surface facing the carrier structure; and
a second, opposite surface facing away from the carrier structure; and
a gate structure,
wherein the gate structure is on the first surface facing the carrier structure;
an insulator region,
wherein the insulator region is on the second, opposite surface facing away from the carrier structure; and
first and second source/drain regions
wherein the first and second source/drain regions are in the epitaxy region.

2. The integrated assembly of claim 1, further comprising:
first and second contact structures that penetrate through the insulator region to the first and second source/drain regions.

3. The integrated assembly of claim 1, further comprising:
a dielectric region including a portion between the gate structure and the carrier structure.

4. The integrated assembly of claim 1, wherein the epitaxy region is a first epitaxy region and further comprising:
a second epitaxy region that is proximate to the first epitaxy region,
wherein surfaces of the first epitaxy region and the second epitaxy region facing the carrier structure share a same, approximately horizontal plane.

5. The integrated assembly of claim 4, wherein a first thickness of the first epitaxy region is less than a second thickness of the second epitaxy region.

6. The integrated assembly of claim 4, wherein the first epitaxy region or the second epitaxy region comprises:
silicon,
gallium arsenide,
indium phosphide,
gallium nitride,
silicon carbide,
a type III-V element, or
silicon germanium.

7. An apparatus, comprising:
a carrier structure;
a dielectric region on the carrier structure;
a gate structure in the dielectric region;
a digit line shield structure that is proximate to the gate structure in the dielectric region;
a first silicon region on the dielectric region, above the gate structure, and having a first thickness;
source/drain regions in the first silicon region;
a second silicon region on the dielectric region, proximate to the first silicon region, and having a second thickness that is greater than the first thickness; and
an isolation region between the first silicon region and the second silicon region and having a same approximate thickness as the second thickness.

8. The apparatus of claim 7, wherein surfaces of the first silicon region and the second silicon region share a same, approximately horizontal plane with a surface of the dielectric region.

9. The apparatus of claim 7, further comprising:
a first digit line structure, and
a second digit line structure that is proximate to the first digit line structure,
wherein the first digit line structure and the second digit line structure are on a surface, of the second silicon region, that faces the carrier structure.

10. The apparatus of claim 9, wherein a portion of the digit line shield structure is between the first digit line structure and the second digit line structure.

11. The apparatus of claim 7, wherein the isolation region is a first isolation region and further comprising:
a second isolation region passing through the second silicon region.

12. The apparatus of claim 11, wherein the first isolation region and the second isolation region have a same approximate thickness as the second silicon region.

13. The apparatus of claim 11, further comprising:
an insulator region on the first silicon region.

14. The apparatus of claim 13 further comprising:
contact structures that penetrate through the insulator region to the source/drain regions.

15. An apparatus, comprising:
a carrier structure;
a first device region, comprising:
a silicon-on-insulator semiconductor structure, comprising:
a first silicon region over a dielectric region;
an insulator region on the first silicon region; and
a gate structure,
wherein the gate structure is between the insulator region and the carrier structure; and
a second device region, comprising:
a memory array structure, comprising:
a second silicon region over the dielectric region,
wherein the second silicon region is proximate to the first silicon region, and
wherein surfaces of the first silicon region and the second silicon region that face the carrier structure share a same, approximately horizontal plane with a surface of the dielectric region that faces away from the carrier structure.

16. The apparatus of claim 15, further comprising:
first and second digit line structures in the memory array structure between the second silicon region and the carrier structure,
wherein surfaces of the first and second digit line structures share the same, approximately horizontal plane.

17. The apparatus of claim 15, further comprising:
an isolation region between the first silicon region and the second silicon region.

18. The apparatus of claim 17, wherein the isolation region joins with the insulator region.

19. The apparatus of claim 17, wherein the isolation region comprises a first thickness, and
wherein the insulator region comprises a second thickness that is less than the first thickness.

20. The apparatus of claim 17, wherein the insulator region joins with the isolation region above an edge of the first silicon region that faces the isolation region.
